(19) United States
(12) Patent Application Publication
(10) Pub. No.: US 2023/0003372 A1
(43) Pub. Date: Jan. 5, 2023

(54) LIGHT SOURCE MODULE

(71) Applicant: Ming-Teng KUO, Tainan City (TW)

(72) Inventor: Ming-Teng KUO, Tainan City (TW)

(21) Appl. No.: 17/563,876

(22) Filed: Dec. 28, 2021

(30) Foreign Application Priority Data
Jul. 4, 2021 (TW) 110124527

(51) Int. Cl. F21V 29/70; F21V 15/01

(52) U.S. Cl. CPC F21V 29/70; F21V 15/01

(57) ABSTRACT

A light source module is provided. The light source module includes a metal substrate, a ceramic substrate, a heat conducting element, and a light emitting unit. The metal substrate has a surface. The ceramic substrate is disposed on the surface of the metal substrate, and the ceramic substrate has an upper surface. The heat conducting element partially covers the upper surface of the ceramic substrate and the surface of the metal substrate. The light emitting unit is disposed on the upper surface of the ceramic substrate. When the light emitting unit emits light, a portion of the heat generated by the light emitting unit is conducted from the ceramic substrate to the metal substrate via the heat conducting element.

### CROSS REFERENCE TO RELATED APPLICATION

This application claims the benefit of Taiwan Patent Application Serial No. 110124527 filed on Jul. 4, 2021, which is incorporated herein by reference.

### BACKGROUND OF THE INVENTION

### 1. Field of the Invention

The present invention relates to a light source module. Specifically, the light source module of the present invention has a heat conducting element partially covering the ceramic substrate and the metal substrate.

### 2. Description of Related Art

Light-emitting diode (LED) has the advantages of power saving, high luminous efficiency, long service life, and fast response speed, and are becoming more and more popular in various light source modules. In terms of vehicle lighting, with the development of electric vehicles in recent years, how to improve the power consumption efficiency or reduce power loss of all electrical equipment (especially vehicle lighting fixtures) is an important issue for the development of electric vehicles.

However, the temperature of the LED will rise sharply when used. If a high-power LED is used to achieve a certain brightness of the lamp, it will be accompanied by the problem of high temperature and heat dissipation. As far as the entire lamp is concerned, the temperature near the LED is getting higher, if the high temperature cannot be effectively dissipated, it will not only affect the luminous efficiency of the LED, but also damage the LED and reduce its service life. From another perspective, if the LED only relies on the back-end heat dissipation components (such as fins, fans, etc.), since the high temperature is still mainly accumulated in the LED, the heat dissipation problem may not be able to solve effectively. It is not easy to get a better heat dissipation structure since the heat dissipation components occupy a large volume and cause power consumption. In other words, high power LEDs are used to increase the brightness of the lamps, and the high temperatures will accumulate in the LED modules. Common solutions are nothing more than reducing the driving power of the LEDs or trying to increase the scale of the back-end heat dissipation components. However, the above methods are obviously not good solutions.

A conventional LED light source module is to dispose the LED die on a ceramic substrate, and then dispose the ceramic substrate on a metal substrate. By the configurations of the copper traces and through holes on the ceramic substrate, the LED on top of the ceramic substrate can be driven to emit light, and part of the heat generated by the LED is conducted to the metal substrate through the lower surface of the ceramic substrate, and then dissipates heat to the rear end (fins, fans and other heat dissipation elements can be placed under the metal substrate). However, not all the unidirectional heat dissipation paths are made of materials with high thermal conductivity, and an insulating layer will inevitably be encountered in the middle which results in an unsatisfactory overall heat dissipation effect, and high temperatures are still accumulated around the LED die.

### SUMMARY OF THE INVENTION

An objective of the present disclosure is to provide a light source module which includes a metal substrate, a ceramic substrate, a heat conducting element, and a light emitting unit. The ceramic substrate is disposed on an upper surface of the metal substrate, the light emitting unit is disposed on an upper surface of the ceramic substrate, and the heat conducting element partially covers the upper surface of the ceramic substrate and the upper surface of the metal substrate. When the light emitting unit emits light, a portion of the heat generated by the light emitting unit is conducted from the upper surface of the ceramic substrate to the upper surface of the metal substrate via the heat conducting element. Accordingly, when the light source module of the present invention is using, in addition to the existing heat dissipation path, a new heat dissipation path is established, that is, the heat is directly conducted from the upper surface of the ceramic substrate to the upper surface of the metal substrate. The starting point of this heat dissipation path is closer to the center of the high temperature of the light emitting unit, so the heat dissipation effect can be increased, the heat can be prevented from accumulating in the light emitting unit, and the work efficiency and service life of the light source module can be improved.

To achieve the aforesaid objective, the present invention discloses a light source module, which includes a metal substrate, a ceramic substrate, a heat conducting element, and a light emitting unit. The metal substrate has a first surface. The ceramic substrate is disposed on the first surface of the metal substrate, the ceramic substrate has an upper surface. The heat conducting element partially covers the upper surface of the ceramic substrate and the first surface of the metal substrate. The light emitting unit is disposed on the upper surface of the ceramic substrate. When the light emitting unit emits light, heat generated by the light emitting unit is partially conducted from the ceramic substrate to the metal substrate via the heat conducting element.

The upper surface of the ceramic substrate has a central area and a peripheral area surrounding the central area, and the light emitting unit is disposed in the central area.

The heat conducting element has a central through hole to expose the central area of the ceramic substrate and the light emitting unit.

The heat conducting element has a first area and a second area surrounding the first area, the first area covers the peripheral area of the upper surface of the ceramic substrate, the second area covers the first surface of the metal substrate.

The heat conducting element further includes a connecting area connected between the first area and the second area.

The connecting area is partially formed with a step difference for avoiding a copper trace on the metal substrate.

The heat conducting element is made of metal material or non-metal material.

In other embodiment, the light source module further includes a heat sink, the metal substrate has a second surface opposite to the first surface, the heat sink is disposed on the second surface, and the heat generated by the light emitting unit partially conducted from the ceramic substrate to the heat sink directly through the metal substrate.

In one embodiment, the light source module further includes a first insulating layer which is disposed between the ceramic substrate and the heat conducting element and between the metal substrate and the heat conducting element.

In one embodiment, the light source module further includes a second insulating layer which is disposed on the second surface of the metal substrate.

In one embodiment, the light source module further includes a third insulating layer which is disposed on a surface, opposite to the metal substrate, of the heat sink.

In one embodiment, the light source module further includes a metal layer formed on the peripheral area of the ceramic substrate for contacting the first area of the heat conducting element.

The detailed technology and preferred embodiments implemented for the present invention are described in the following paragraphs accompanying the appended drawings for people skilled in this field to well appreciate the features of the claimed invention.

### BRIEF DESCRIPTION OF THE DRAWINGS

FIG. 1 is a schematic view of the light source module according to the present invention;

FIG. 2 is a cross sectional view of the light source module according to the present invention;

FIG. 3 is an exploded view of the light source module according to the present invention;

FIG. 4 is an exploded view of the light source module according to the present invention;

FIG. 5 is a cross sectional view of the light source module according to the present invention;

FIG. 6 is a cross sectional view of the light source module having the first insulating layer according to the present invention;

FIG. 7 is a cross sectional view of the light source module having the first insulating layer according to the present invention;

FIG. 8 is a cross sectional view of the light source module having the first insulating layer according to the present invention;

FIG. 9 is a cross sectional view of the light source module of another embodiment according to the present invention; and

FIG. 10 is a cross sectional view of the light source module of another embodiment according to the present invention.

### DETAILED DESCRIPTION OF THE PREFERRED EMBODIMENT

Reference will now be made in detail to the present embodiments of the invention, examples of which are illustrated in the accompanying drawings, and are not intended to limit the present invention, applications or particular implementations described in these embodiments. Wherever possible, the same reference numbers are used in the drawings and the description to refer to the same or like parts. It shall be appreciated that, in the following embodiments and the attached drawings, elements unrelated to the present invention are omitted from depiction; and dimensional relationships among individual elements in the attached drawings are provided only for ease of understanding, but not to limit the actual scale.

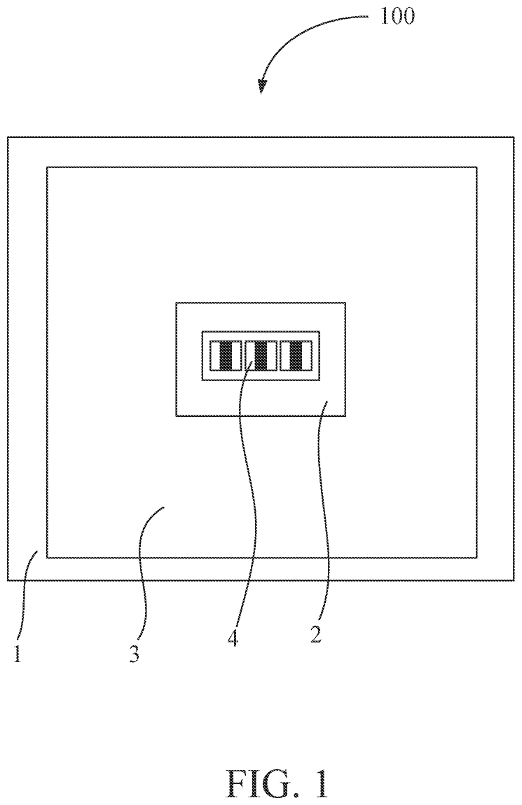

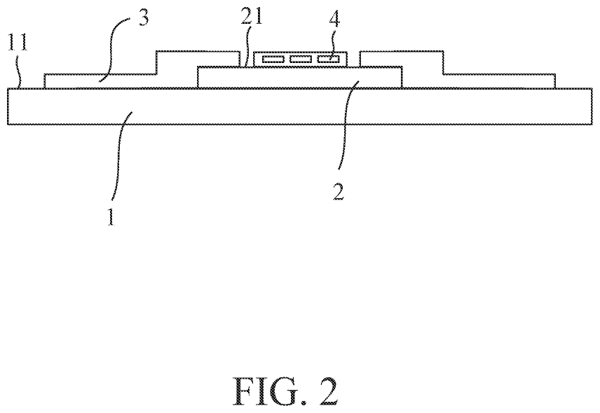

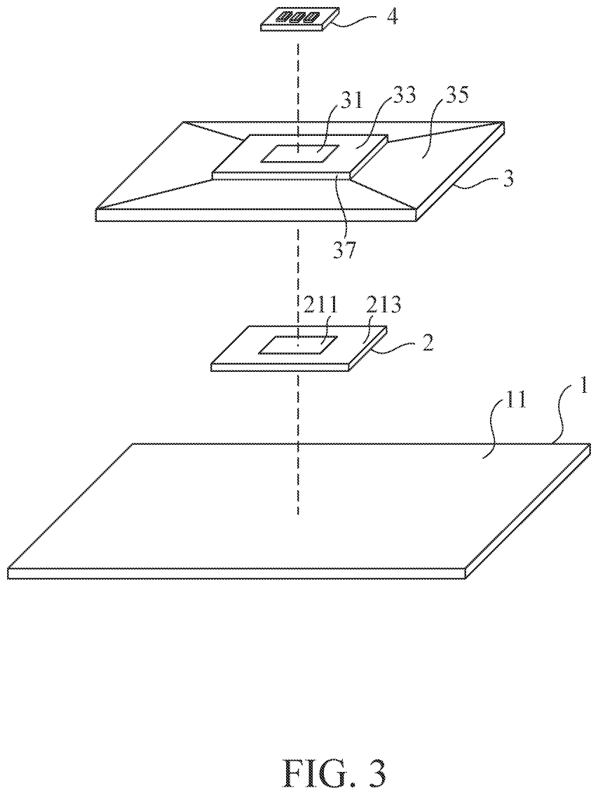

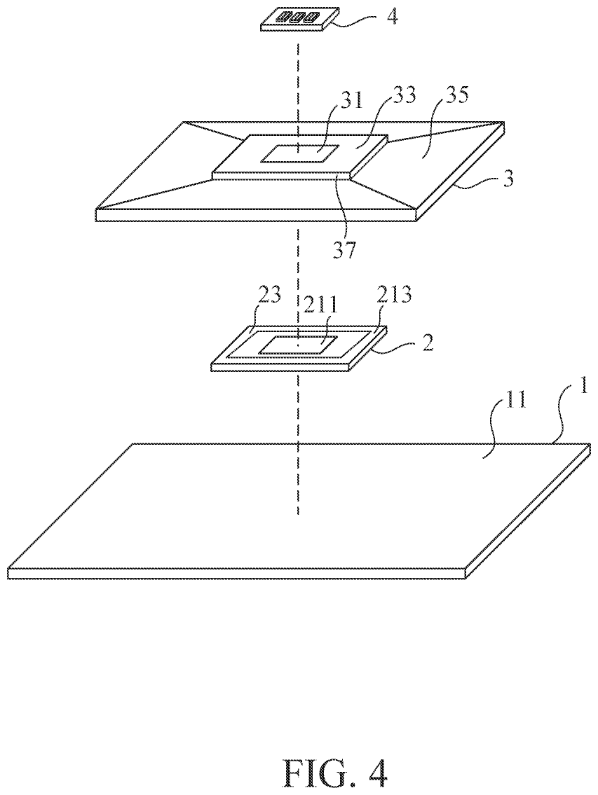

Reference is made to FIG. 1 and FIG. 2. FIG. 1 is a schematic view of the light source module 100 of the present invention, and FIG. 2 is a cross sectional view of the light source module 100 of the present invention. The light source module 100 includes a metal substrate 1, a ceramic substrate 2, a heat conducting element 3, and a light emitting unit 4. The metal substrate 1 has a first surface 11, the ceramic substrate 2 is disposed on the first surface 11 of the metal substrate 1, and the ceramic substrate 2 has an upper surface 21. Please refer to FIG. 3 and FIG. 4, which are exploded views of the light source module 100 of the present invention. The upper surface 21 of the ceramic substrate 2 has a central area 211 and a peripheral area 213 surrounding the central area 211. In a preferred embodiment, the ceramic substrate 2 further includes a metal layer 23, and the light emitting unit 4 is disposed on the central area 211 of the upper surface 21 of the ceramic substrate 2. The metal layer 23 is formed on the peripheral area 213 of the upper surface 21 of the ceramic substrate 2, and the metal layer 23 is used to quickly conduct the heat of the upper surface 21 of the ceramic substrate 2 to the heat conducting element 3.

The heat conducting element 3 partially covers the upper surface 21 of the ceramic substrate 2 and the first surface 11 of the metal substrate 1. Specifically, the heat conducting element 3 has a central through hole 31, a first area 33, a second area 35, and a connecting area 37. The size of the central through hole 31 is smaller than the area of the upper surface 21 of the ceramic substrate 2 and greater than or equal to the area of the central area 211 of the upper surface 21. The second area 35 surrounds the first area 33, and the first area 33 and the second area 35 partially overlap, and the connecting area 37 is connected between the first area 33 and the second area 35.

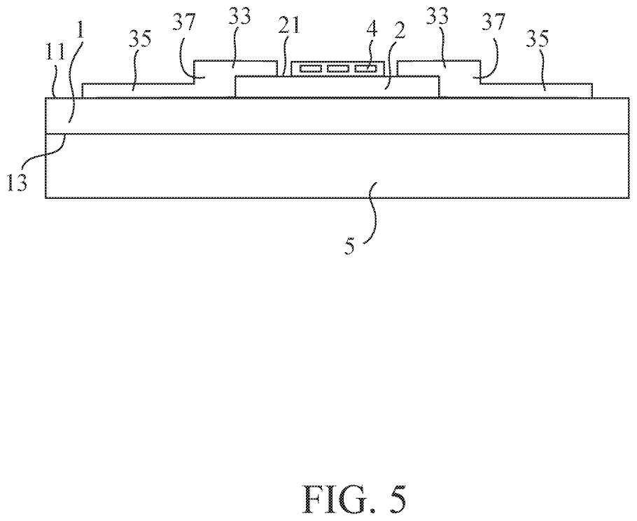

In this embodiment, the cross section of the first area 33, the connecting area 37, and the second area 35 are generally in stepped shape (as shown in FIG. 5) to simultaneously cover the peripheral area 213 of the ceramic substrate 2 and the first area 11 of the metal substrate 1. In detail, when the heat conducting element 3 covers the ceramic substrate 2, the first area 33 of the heat conducting element 3 covers the peripheral area 213 of the upper surface 21 of the ceramic substrate 2, so the metal layer 23 of the ceramic substrate 2 and the first area 33 of the heat conducting element 3 contacts. The second area 35 of the heat conducting element 3 covers the first surface 11 of the metal substrate 1, and the central through hole 31 can expose the central area 211 of the ceramic substrate 2 and the light emitting unit 4, thus the light generated by the light emitting unit 4 can penetrates through the central through hole 31. The light emitting unit 4 may be a light-emitting diode (LED) module, but is not limited thereto. When the light emitting unit 4 emits light, part of the heat generated by the light emitting unit 4 is conducted from the peripheral area 21 of the upper surface 21 of the ceramic substrate 2, the metal layer 23, and then to the metal substrate 1 via the heat conducting element 3. In addition, the heat conducting element 3 can be made of a metal material with high thermal conductivity (e.g., copper, aluminum) or non-metallic materials (e.g., High thermal conductivity ceramics) to quickly dissipate heat close to the light emitting unit 4 as much as possible to prevent the temperature of the light emitting unit 4 from being too high.

In other embodiments, referring to FIG. 5, the light source module 100 further includes a heat sink 5, the metal substrate 1 has a second surface 13 opposite to the first surface 11, and the heat sink 5 is disposed on the second surface 13. After the heat generated by the light emitting unit 4 is conducted from the metal layer 23 of the ceramic substrate 2 to the metal substrate 1 via the heat conducting element 3, the metal substrate 1 will further conduct the heat to the heat sink 5. In addition, another part of the heat generated by the light emitting unit 4 is still directly conducted from the lower surface of the ceramic substrate 2 to the heat sink 5 via the metal substrate 1.

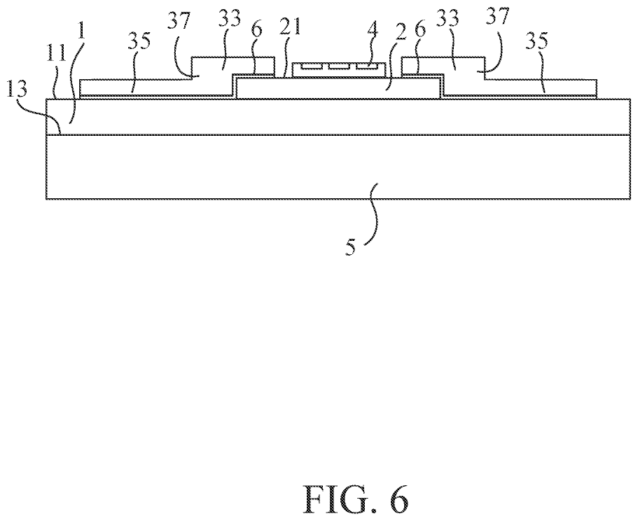

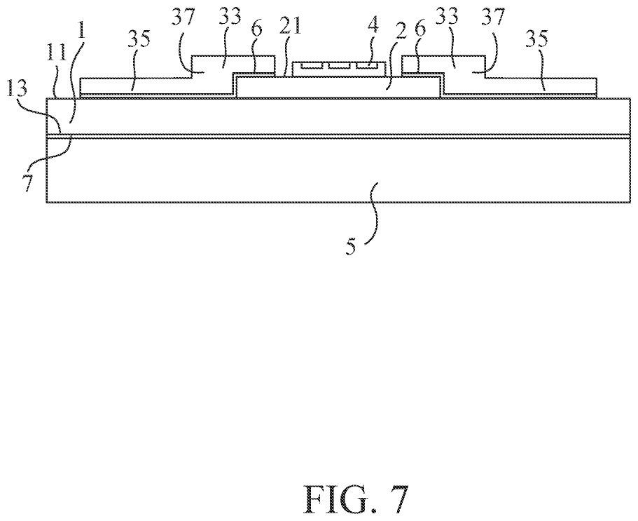

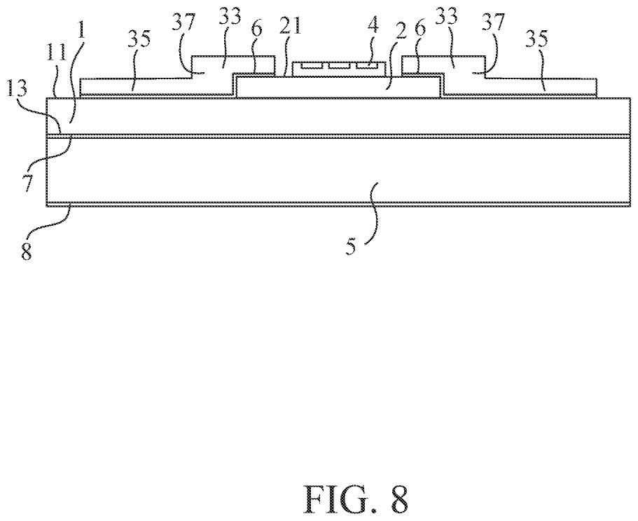

In other embodiments, the light source module 100 further includes at least one insulating layer to avoid short circuits or to isolate the light source module 100 from other components. To be more specific, referring to FIG. 6, the light source module 100 further includes a first insulating layer 6 which is disposed between the ceramic substrate 2 and the heat conducting element 3 and between the metal substrate 1 and the heat conducting element 3. In addition, please refer to FIG. 7, the light source module 100 further includes a second insulating layer 7 disposed on the second surface 13 of the metal substrate 1 to avoid short circuits. In FIG. 8, the light source module 100 further includes a third insulating layer 8 disposed on the surface, opposite to the metal substrate 1, of the heat sink 5. When the light source module 100 is assembled with other parts or accessories such as lamps, the third insulating layer 8 can protect the light source module 100 by preventing the light source module from being affected when other assembled parts or accessories are damaged.

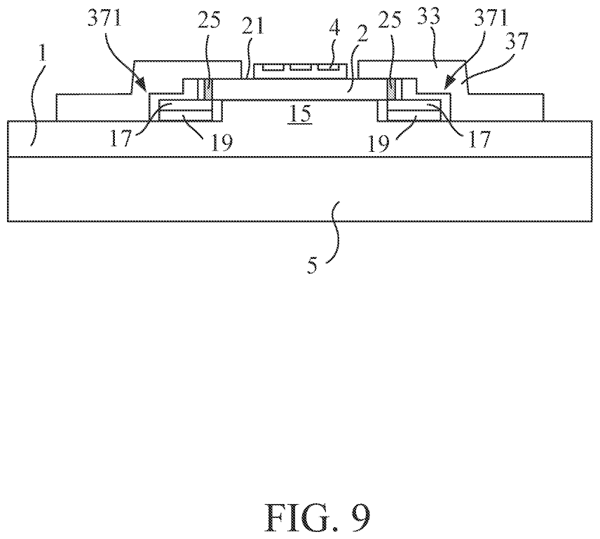

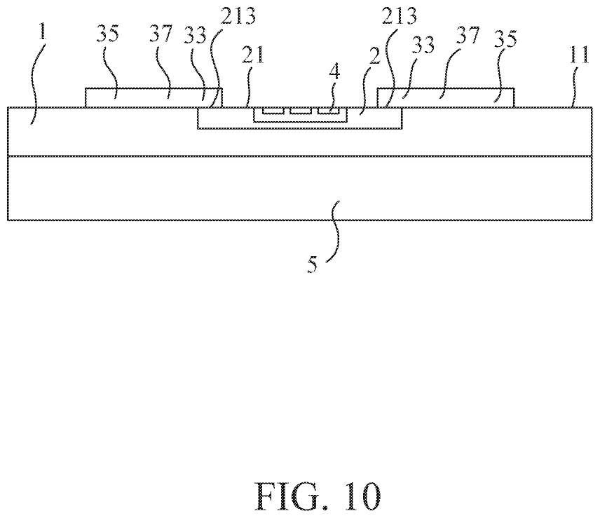

Reference is made to FIG. 9 for another embodiment of the present invention. In this embodiment, the metal substrate 1 further has a copper bump 15 for the ceramic substrate 2 to be disposed. The copper bump 15 directly contacts the lower surface of the ceramic substrate 2 to ensure that the heat of the ceramic substrate 2 can be conducted to the metal substrate 1. In addition, the copper traces 17 and corresponding insulating layers 19 are partially formed on the metal substrate 1. The copper traces 17 are connected to the upper surface 21 through the through holes 25 of the ceramic substrate 2 and are then electrically connected to the light emitting unit 4 for supplying electricity to light up the light emitting unit 4. As shown in the figures, the connecting area 37 is partially formed with a step difference 371 for avoiding the copper traces 17 on the metal substrate 1. In another embodiment, as shown in FIG. 10, the metal substrate 1 may form with a concave area for accommodating the ceramic substrate 2 to make the upper surface 21 of the ceramic substrate 2 and an upper surface of the metal substrate 1 become coplanar. Under the circumstances, the heat conducting element 3 is designed as a plate shape instead of step difference shape. Thus, the first area 33 is located at the innermost side and contacts the peripheral area 213 of the upper surface 21 of the ceramic substrate 2, the connecting area 37 surrounds the first area 33, and the second area 35 is located at the outermost surrounding the connecting area 37 and contacting with the first surface 11 of the metal substrate 1.

According to the above, the light source module of the present invention has an additional heat conduction path by partially covering the upper surface of the ceramic substrate and the upper surface of the metal substrate by the heat conducting element. The heat conduction path directly conducts the heat from the upper surface of the ceramic substrate (which is closest to the light emitting unit and is most common in heat accumulation) to the metal substrate to further dissipate to the rear end, thereby increasing the heat dissipation effect of the light emitting unit when it emits light, avoiding heat accumulation in the light emitting unit, and improving the working efficiency and service life of the light source module. Besides, insulating layers are disposed at different positions to ensure that the light emitting unit will not be short-circuited and will not be affected by other external parts.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A light source module, comprising:
a metal substrate having a first surface;
a ceramic substrate being disposed on the first surface of the metal substrate, the ceramic substrate having an upper surface;
a heat conducting element partially covering the upper surface of the ceramic substrate and the first surface of the metal substrate; and
a light emitting unit being disposed on the upper surface of the ceramic substrate;
wherein when the light emitting unit emits light, heat generated by the light emitting unit is partially conducted from the ceramic substrate to the metal substrate via the heat conducting element.

2. The light source module as claimed in claim 1, wherein the upper surface of the ceramic substrate has a central area and a peripheral area surrounding the central area, and the light emitting unit is disposed in the central area.

3. The light source module as claimed in claim 2, wherein the heat conducting element has a central through hole to expose the central area of the ceramic substrate and the light emitting unit.

4. The light source module as claimed in claim 3, wherein the heat conducting element has a first area and a second area surrounding the first area, the first area covers the peripheral area of the upper surface of the ceramic substrate, and the second area covers the first surface of the metal substrate.

5. The light source module as claimed in claim 4, wherein the heat conducting element further comprises a connecting area connected between the first area and the second area.

6. The light source module as claimed in claim 5, wherein the connecting area is partially formed with a step difference for avoiding a copper trace on the metal substrate.

7. The light source module as claimed in claim 4, wherein the heat conducting element is made of metal material or non-metal material.

8. The light source module as claimed in claim 4, further comprising a heat sink, wherein the metal substrate has a second surface opposite to the first surface, the heat sink is disposed on the second surface, and the heat generated by the light emitting unit is partially conducted from the ceramic substrate to the heat sink directly through the metal substrate.

9. The light source module as claimed in claim 8, further comprising a first insulating layer being disposed between the ceramic substrate and the heat conducting element and between the metal substrate and the heat conducting element.

10. The light source module as claimed in claim 8, further comprising a second insulating layer being disposed on the second surface of the metal substrate.

11. The light source module as claimed in claim 8, further comprising a third insulating layer being disposed on a surface, opposite to the metal substrate, of the heat sink.

12. The light source module as claimed in claim 4, wherein the ceramic substrate further comprises a metal layer formed on the peripheral area of the ceramic substrate for contacting the first area of the heat conducting element.
